(19) United States
(12) Patent Application Publication
(10) Pub. No.: US 2017/0237284 A1
(43) Pub. Date: Aug. 17, 2017

(54) SOLAR CHARGING APPARATUS

(71) Applicant: Mark Summers, Orem, UT (US)

(72) Inventor: Mark Summers, Orem, UT (US)

(21) Appl. No.: 15/431,737

(22) Filed: Feb. 13, 2017

Related U.S. Application Data
(60) Provisional application No. 62/295,050, filed on Feb. 13, 2016.

(51) Int. Cl. H02J 7/35; H01L 31/0384; A42B 1/24; H02J 7/00; A42B 1/04; A42B 1/06; H02S 40/38; H01L 31/0216

(52) U.S. Cl. CPC H02J 7/355; H02S 40/38; H01L 31/0384; H01L 31/02168; H02J 7/007; A42B 1/041; A42B 1/062; A42B 1/24

(57) ABSTRACT

A solar charging apparatus is disclosed that includes an article of apparel that is capable of conformably fitting to a body part of a wearer, the article of apparel having a longitudinal dimension and a transversal dimension. The apparatus includes a power source that is coupleable to an interior portion of the article of apparel. The power source is connected to an output connector that is configured to charge a portable electronic device that is separate from the article of apparel. The apparatus includes a plurality of crystalline solar cells for recharging the power source, wherein the plurality of crystalline solar cells curves to conform to the article of apparel.

### FIELD

This invention relates to a solar charging apparatus and more particularly relates to solar charging apparatus that include an article of apparel.

### BACKGROUND

Many different types of portable electronic devices such as smart phones, music players, radios and the like are powered by batteries. Typical portable electronic devices may be charged using an AC to DC power adapter that charges the portable electronic devices from a stationary position, e.g., a power outlet in a home or an office.

Different types of solar cells exist which may be used to supply power to various articles such as for example a solar powered radio.

### SUMMARY

A solar charging apparatus is disclosed. In one embodiment, the solar charging apparatus includes an article of apparel that is capable of conformably fitting to a body part of a wearer, the article of apparel having a longitudinal dimension and a transversal dimension. In the embodiment, the solar charging apparatus further includes a power source that is coupleable to an interior portion of the article of apparel, the power source connected to an output connector that is configured to charge a portable electronic device that is separate from the article of apparel. The solar charging apparatus further includes a plurality of crystalline solar cells for recharging the power source, wherein the plurality of crystalline solar cells curves to conform to the article of apparel.

In another embodiment, a method of manufacturing a solar charging article of apparel is disclosed. In the embodiment, the method includes covering an uncut crystalline solar cell with a flexible top layer. The method further includes cutting the uncut crystalline solar cell into strips and curve at angled pre-stressed lines. The method includes attaching the strips to the article of apparel so as to conform to the article of apparel and electrically connecting the strips together.

In another embodiment, a system for charging a portable electronic device is disclosed that includes an article of head apparel that is capable of conformably fitting to a body part of a wearer. In the embodiment, the system further includes a power source that is coupleable to an interior portion of the article of head apparel, the power source connected to an output connector that is configured to charge a portable electronic device that is separate from the article of head apparel. The system further includes, a plurality of crystalline solar cells for recharging the power source, wherein the plurality of crystalline solar cells curves to conform to the article of head apparel.

### BRIEF DESCRIPTION OF THE DRAWINGS

In order that the advantages of the invention will be readily understood, a more particular description of the invention briefly described above will be rendered by reference to specific embodiments that are illustrated in the appended drawings. Understanding that these drawings depict only typical embodiments of the invention and are not therefore to be considered to be limiting of its scope, the invention will be described and explained with additional specificity and detail through the use of the accompanying drawings, in which:

FIG. 1 is perspective view illustrating one embodiment of a solar charging apparatus that includes an article of apparel.

FIG. 2 is a top view illustrating an embodiment of a solar-powered system for charging a separate portable electronic device.

FIG. 3 is a front view of the embodiment of FIG. 2;

FIG. 4 is a side view of the embodiment of FIG. 2;

FIG. 5A is a top view of an uncut crystalline solar cell suitable for use in the solar charging article of apparel of FIG. 1 and FIG. 2;

FIG. 5B is a cross-sectional view of the uncut crystalline solar cell of FIG. 5A with an anti-reflective layer applied on a top surface of the crystalline solar cell;

FIG. 5C illustrates a top view of strips cut from the crystalline solar cell of FIG. 5B with polarity markings and further showing electrical connections between the strips, a regulator, and a rechargeable power source;

FIG. 5D illustrates a top view of strips cut from the crystalline solar cell and pre-stressed to enable the crystalline solar cell to curve while continuing to function;

FIG. 5E illustrates a top view of strips attached to a flexible substrate for attaching so that the curvature of the substrate conforms to the article apparel;

FIG. 6 is a schematic flow diagram illustrating one embodiment of a method of manufacturing a solar charging apparatus in accordance with one embodiment;

FIG. 7 is a schematic flow diagram illustrating another embodiment of a method of manufacturing a solar charging apparatus in accordance with some embodiments.

### DETAILED DESCRIPTION

Reference throughout this specification to “one embodiment,” “an embodiment,” or similar language means that a particular feature, structure, or characteristic described in connection with the embodiment is included in at least one embodiment. Thus, appearances of the phrases “in one embodiment,” “in an embodiment,” and similar language throughout this specification may, but do not necessarily, all refer to the same embodiment, but mean “one or more but not all embodiments” unless expressly specified otherwise. The terms “including,” “comprising,” “having,” and variations thereof mean “including but not limited to” unless expressly specified otherwise. An enumerated listing of items does not imply that any or all of the items are mutually exclusive and/or mutually inclusive, unless expressly specified otherwise. The terms “a,” “an,” and “the” also refer to “one or more” unless expressly specified otherwise.

Furthermore, the described features, structures, or characteristics of the invention may be combined in any suitable manner in one or more embodiments. In the following description, numerous specific details are provided, such as examples of programming, software modules, hardware modules, hardware circuits, hardware chips, etc., to provide a thorough understanding of embodiments of the invention. One skilled in the relevant art will recognize, however, that the invention may be practiced without one or more of the specific details, or with other methods, components, materials, and so forth. In other instances, well-known structures, materials, or operations are not shown or described in detail to avoid obscuring aspects of the invention.

The schematic flow chart diagrams included herein are generally set forth as logical flow chart diagrams. As such, the depicted order and labeled steps are indicative of one embodiment of the presented method. Other steps and methods may be conceived that are equivalent in function, logic, or effect to one or more steps, or portions thereof, of the illustrated method. Additionally, the format and symbols employed are provided to explain the logical steps of the method and are understood not to limit the scope of the method. Although various arrow types and line types may be employed in the flow chart diagrams, they are understood not to limit the scope of the corresponding method. Indeed, some arrows or other connectors may be used to indicate only the logical flow of the method. For instance, an arrow may indicate a waiting or monitoring period of unspecified duration between enumerated steps of the depicted method. Additionally, the order in which a particular method occurs may or may not strictly adhere to the order of the corresponding steps shown.

It should also be noted that, in some alternative implementations, the functions noted in the block may occur out of the order noted in the Figures. For example, two blocks shown in succession may, in fact, be executed substantially concurrently, or the blocks may sometimes be executed in the reverse order, depending upon the functionality involved. Other steps and methods may be conceived that are equivalent in function, logic, or effect to one or more blocks, or portions thereof, of the illustrated Figures.

Although various arrow types and line types may be employed in the flowchart and/or block diagrams, they are understood not to limit the scope of the corresponding embodiments. Indeed, some arrows or other connectors may be used to indicate only the logical flow of the depicted embodiment. For instance, an arrow may indicate a waiting or monitoring period of unspecified duration between enumerated steps of the depicted embodiment. It will also be noted that each block of the block diagrams and/or flowchart diagrams, and combinations of blocks in the block diagrams and/or flowchart diagrams, can be implemented by special purpose hardware-based systems that perform the specified functions or acts, or combinations of special purpose hardware and program code.

Hats are commonly used outdoors, where there is often abundant sunlight. This sunlight can be harnessed by solar power chargers to charge an electronic device.

Since solar power is available for much of the day, charging an electronic device using solar power is advantageous because it does not require a user to remember to plug the electronic device into a conventional AC-to-DC charger for charging at night. Further, if the user will be using the electronic device for an extended period of time outdoors, charging electronic device using solar power provides a constant charging source while sunlight is available, thus effectively extending battery life significantly.

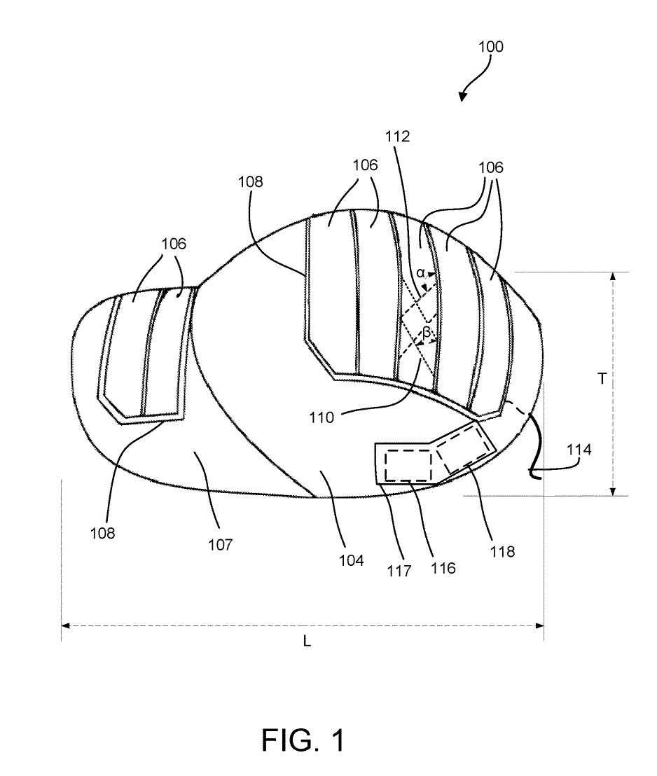

FIG. 1 is perspective view illustrating one embodiment of an apparatus 100 for solar charging that includes an article of apparel 104. The article of apparel 104 article of apparel is capable of conformably fitting to a body part of a wearer. One example of an article of apparel 104 is a baseball cap that conformably fits to a wearer's head. In other words, the curvature of the article of apparel 104 e.g., a baseball cap conformably fits to the curvature of a wearer's head. It may be noted that conformably fitting to a body part of a wearer may refer to a human wearer in some embodiments. In other embodiments, the article of apparel 104 may be something other than a baseball cap such as for example a harness that conformably fits to a body part of an animal wearer. In the embodiment, the article of apparel 104 has a longitudinal dimension 1′ and a transversal dimension ‘T.’

In the embodiment, the apparatus 100 further includes a power source 117 that is coupleable to an interior portion of the article of apparel 104, the power source 117 is connected to an output connector 114 that is configured to charge a portable electronic device (not shown) that is separate from the article of apparel.

In the embodiment, the apparatus 100 further includes a plurality of crystalline solar cells 106 for recharging the power source 117, wherein the plurality of crystalline solar cells curves to conform to the article of apparel 104. In other words, the crystalline solar cells 106 are formed to have a curvature that generally conforms to a curvature of article of apparel 104.

In some embodiments, the crystalline solar cells 106 are monocrystalline solar cells. Polycrystalline solar cells also exist. However, because polycrystalline solar cells generally have lower silicon purity than monocrystalline solar cells, polycrystalline solar cells are generally less efficient than monocrystalline solar cells. Likewise, amorphous thin film solar panels or cells are typically also less efficient than monocrystalline solar cells. One type of monocrystalline solar cells is the Maxeon® solar cells available from Sun power® Corporation of 77 Rio Robles, San Jose, Calif. 95134.

Monocrystalline solar cells are generally inherently planar because they are manufactured from silicon wafers. Silicon wafers are generally fragile and subject to breakage. Thus, vendors of apparatuses that include monocrystalline solar cells generally strongly caution against bending or curving the monocrystalline solar cells. In some cases, any warranty relating to the functionality of monocrystalline solar cells may be affected if the solar cells are curved or bent.

In some embodiments, crystalline solar cells 106 are prepared so as to achieve a curvature that allows the crystalline solar cells 106 to conform to the curvature of the article of apparel 104. For example, in the embodiment depicted in FIG. 1 the crystalline solar cells 106 have been pre-stressed at a first predetermined angle a at dashed line 112 and also pre-stressed at a second predetermined angle 13 at dotted line 110. The pre-stress line 112 (dashed) and the pre-stress line 110 (dotted) are merely exemplary and each of the crystalline solar cells 106 (e.g., strips) may be pre-stressed add a number of positions along the length of each crystalline solar cell 106.

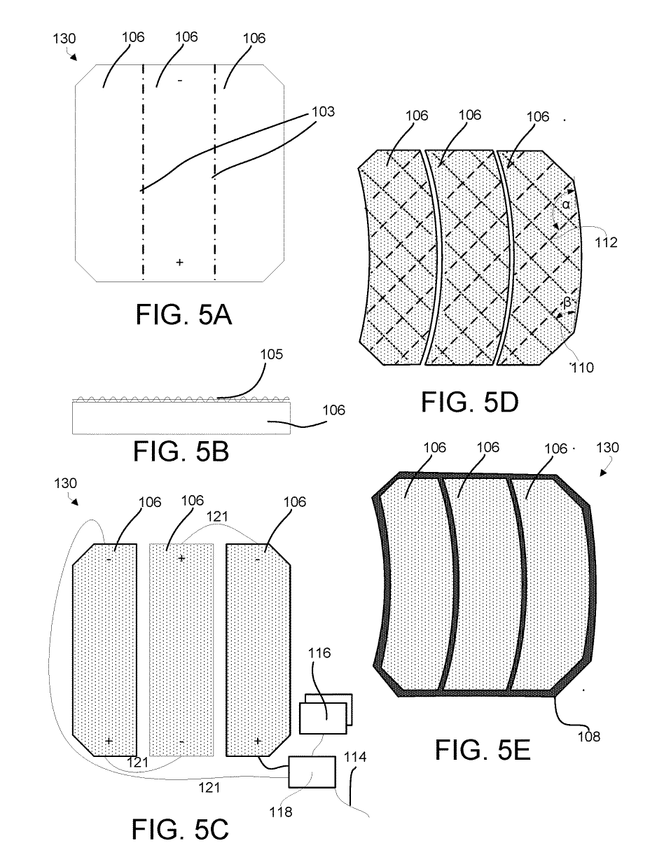

The first predetermined angle α and the second predetermined angle β may be non-perpendicular to long edges of the crystalline solar cells 106 (e.g., strips). In some embodiments, an angle α in the range of 120° to 150° give suitable results and an angle β in the range of 30° to 60° gives suitable results. In other embodiments, other angles α and β may also give suitable results. Use of relatively consistent angles has an advantage of creating an aesthetically pleasing tessellated pattern, but the angles need not be consistent nor need they be at a particular angle in order to achieve at least some degree of functionality. More about the method of manufacturing the plurality of crystalline solar cells 106 so that they have a degree of curvature to conform to the article of apparel 104 is described below with respect to FIG. 5A through FIG. 7.

In some embodiments, the apparatus 100 further includes a flexible substrate 108 which acts as a tray to which the plurality of crystalline solar cells 106 (e.g., strips) may be attached. The curvature of the crystalline solar cells 106, is generally achieved in two ways. In one embodiment, the plurality of crystalline solar cells comprises strips of a crystalline solar cell that have had a top layer (not shown) attached. The top layer keeps the solar cell together and functional even when it is curved along the pre-stressed lines 110 and 112. More about how this top layer affects the curvature is described below with respect to FIG. 5A.

Using a plurality of crystalline solar cells 106 that have been prepared to allow for curvature, e.g., along the length of each strip as illustrated in FIG. 1, the flexible substrate 108 and the attached plurality of crystalline solar cells 106 may curve to conform along a transversal dimension ‘T’ of the article of apparel 104. In this case, the transversal dimension ‘T’ refers generally to the width from one side of the baseball cap to the other side of the baseball cap.

In some embodiments, the plurality of crystalline solar cells 106 is arranged with disjunction or space between each crystalline solar cell 106. Because the underlying material, e.g., flexible substrate 108 or material of the article of apparel 104 is flexible, the plurality of crystalline solar cells 106 may curve by articulating along the longitudinal dimension, e.g the front to back. In other words, the strips of the plurality of crystalline solar cells 106 are sufficiently thin and are spaced apart with sufficient space to allow them to move and flex to conform with the curvature of the article of apparel 104.

In this example, the articulation of the strips of the plurality of crystalline solar cells 106 Curves to conform to a longitudinal dimension of the article of apparel 104. It may be noted that transversal dimension T and longitudinal dimension L I intended to denote general directions e.g., length and width and are not intended to limited to the length and width at a particular point such as for example the bottom rim of the baseball cap.

In some embodiments, the plurality of crystalline solar cells 106 comprises a flexible top layer (not shown) that covers the crystalline solar cells, which will be described further below with retrospective FIGS. 5A through 7.

The flexible substrate 108 may be any size. In general, as the area of the crystalline solar cells 106 increases the total amount of energy from solar power also increases. In some embodiments, the dimensions of the crystalline solar cells 106 (e.g., strips) are determined by the availability of a particular size of monocrystalline solar cells.

In some embodiments, the article of apparel 104 may be selected from the group consisting of baseball caps, military caps, driving caps, beanies, stocking caps, sun hats, bucket hats, and ski masks. All of these articles of apparel have flexibility and conform to a wearer's body part such as a wearer's head.

It may be noted, that is used herein the term “article of apparel that is capable of conformably fitting to a body part of a wearer” means that at least a portion of the article of apparel 104 fits in a way that generally conforms to a body part of where. In some embodiments, the article of apparel 104 may include an extension 107, such as for example a brim of a baseball cap or other type of hat.

As used herein, the term “wherein the plurality of crystalline solar cells curves to conform to the article of apparel” means that the plurality of crystalline solar cells curves to conform to at least a portion of the article of apparel. Moreover, as described above, the curvature of the crystalline solar cells 106 may be achieved by curbing the crystalline solar cells 106 along pre-stressed lines 110 and 112.

The curvature of crystalline solar cells may also be achieved by arranging the plurality of crystalline solar cells 106 such that they curve in an articulating fashion, e.g., as shown with the five crystalline solar cells 106 shown at the top of the baseball cap depicted in FIG. 1.

In some embodiments, the power source 117 includes at least one rechargeable battery 116. In some embodiments, the at least one rechargeable battery 116 includes a lithium-ion chemistry. For example, the lithium-ion chemistry includes iron phosphate. Hence batteries using this chemistry are sometimes called lithium-ion phosphate batteries (“LiFePO₄”) and are also called “LFP” batteries. Lithium iron phosphate chemistries may provide advantages with regard to high-power density and high energy density as well as excellent safety performance and extensive cycle life in a light weight compact package. With regard to safety, various types of LFP batteries are less susceptible to combustion or overheating then conventional lithium-ion polymer batteries that do not include lithium iron phosphate chemistries.

In some embodiments, the apparatus 100 further includes a regulator 118 that is configured to regulate an output of the plurality of crystalline solar cells 106 to provide a predetermined voltage for charging the at least one rechargeable battery 116. For example, in some embodiments, the power regulator may regulate the voltage to provide a voltage in the range of about 3.0 V to about 3.8 V. The output current of the regulator generally depends upon the output current of the crystalline solar cells 106. The plurality of crystalline solar cells 106 may be connected in series to provide a predetermined voltage. Likewise, some of the plurality of crystalline solar cells 106 may be connected in parallel to provide a predetermined maximum current.

A typical current at and output of the plurality of crystalline solar cells 106 will depend on how the plurality of crystalline solar cells 106 are connected as well as the amount of solar radiation being received at the plurality of crystalline solar cells 106.

One additional advantage of the curvature of using a plurality of crystalline solar cells 106 that conforms to the article of apparel is that direct solar radiation may be received at different times of the day when the sun is at different points in the sky that would be possible if the apparatus used conventional planer crystalline solar cells, which receive maximum direct radiation when the sun is directly perpendicular to the plane of the un-curved crystalline solar cells.

The apparatus 100 may also be used in a system that is configured to charge a portable electronic device. For example, in some embodiments, a system 200 includes an article of head apparel that is capable of conformably fitting to a body part of a wearer. In the embodiment, the article of head apparel as a longitudinal dimension L and a transversal dimension T. It may be noted that the longitudinal dimension L and the transversal dimension T are arbitrary dimensions that are different relative to each other. For example, in some embodiments, such as in a solar charging shoulder pad, a longitudinal dimension L may be from neck to arm and transversal dimension T may be from front to back.

In some embodiments, it is advantageous to arrange the plurality of crystalline solar cells 106 (e.g., strips) such that they are attached so as to articulate along longest dimension of the article of apparel, which in this case is front to back. In the embodiments, the plurality of crystalline solar cells 106 (e.g., strips) are curved along pre-stress lines 110 and 112 so as to conform to the curvature along the shortest dimension of the article of apparel 104 (e.g., baseball cap), which in this case is side to side.

In some embodiments, the apparatus 100 may further include an output connector 114, which is depicted as a cable but which also may include a plug or a jack. The output connector 114 may be electrically connected to the power source 117. In some embodiments, the voltage required at the output connector 114 may be higher than the voltage provided by the plurality of crystalline solar cells 106. In such an embodiment, the regulator 118 may boost the voltage of the plurality of crystalline solar cells 106 and/or the at least one rechargeable battery 116 so as to provide a predetermined voltage.

For example, some Universal Serial Bus (“USB”) standards require a 5V charging voltage. In some embodiments, the regulator 118 may boost output from a 3.2V battery or a 3.6V battery to provide a 5V output at the output connector 114. It may be noted that any type of regulator 118 may be used. In some embodiments, the regulator 118 may be controlled by a microprocessor and the output connector 114 may include signal conductors that allow a regulator when 18 with a microprocessor and other appropriate circuitry to receive signals in order to more effectively regulate a voltage of the output connector 114.

In some embodiments, the apparatus 100 may further include an input connector for providing power to charge the at least one rechargeable battery independently from the plurality of crystalline solar cells. For example, a user of the apparatus 100 may want to charge the at least one rechargeable battery at a time when no sunlight is available. In such a circumstance, the user may connect a power source to the input connector to charge the at least one rechargeable batteries so that it is fully charged before the apparatus 100 is used.

In other embodiments, the regulator 118 may include a microprocessor that program code in a software module to switch the output at an appropriate timing interval. For example, in some embodiments, the regulator 118 includes a microprocessor that executes program code software module to switch the output on only every five minutes. By so doing, the regulator 118 may minimize unnecessary discharge of a battery of a mobile device that is connected to output connector 114. For example, many smartphones use increased power when a charger his first connected or first begins to charge. By regulating this output to minimize the frequency with which a discharged at least one rechargeable battery 116 causes the output of the regulator 118 to turn on and off, a rate of power consumption of the smart phone battery is reduced.

In some embodiments, the apparatus 100 further includes a breathable liner (not shown) configured to attach to the article of apparel and to separate the at least one rechargeable battery from the body part of the wearer. The breathable liner may be made of any suitable material for lining a particular type of apparel.

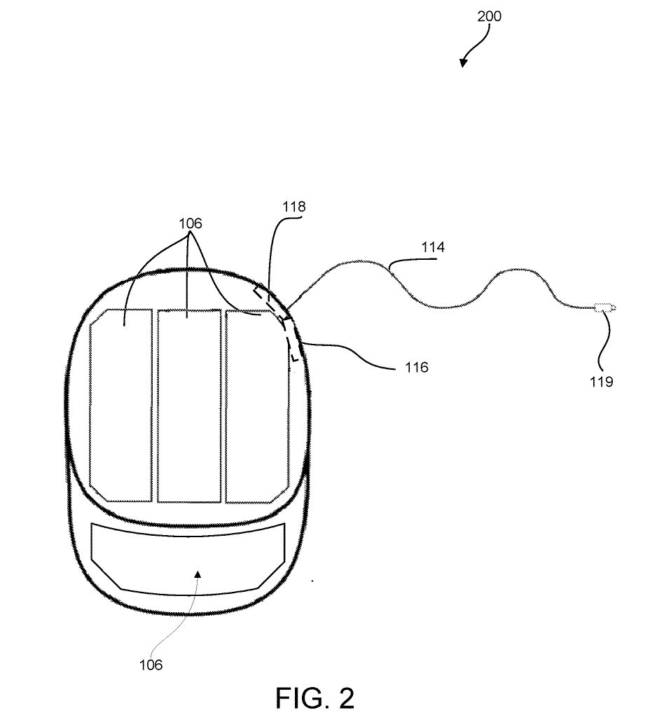

FIGS. 2-4 depict another embodiment of a system 200 for charging a portable electronic device. FIG. 2 is a top view illustrating a system 200 for charging a portable electronic device (not shown) that is separate from an article of apparel 104. As used herein, the term “separate from an article of apparel” means that the portable electronic device is not attached to the article of apparel 104. For example, one or more light emitting diodes or other light devices in which the light emitting diodes or the other light devices are attached to the and article of apparel such as a hat would not be considered to meet the definition provided herein of a portable electronic device that is “separate from an article of apparel.”

In some embodiments, the system 200 includes an output connector 114 such as a cable that enables a portable electronic device to receive power for charging, such as for example, through a plug 119. As explained above with respect to FIG. 1, the output connector 114 may be a plug, a jack, an adapter, a cable, or any combination thereof as would be apparent to one of skill in the art. In some embodiments as explained above, not every portion of the article of apparel 104 needs to have a curvature that conforms to a body part.

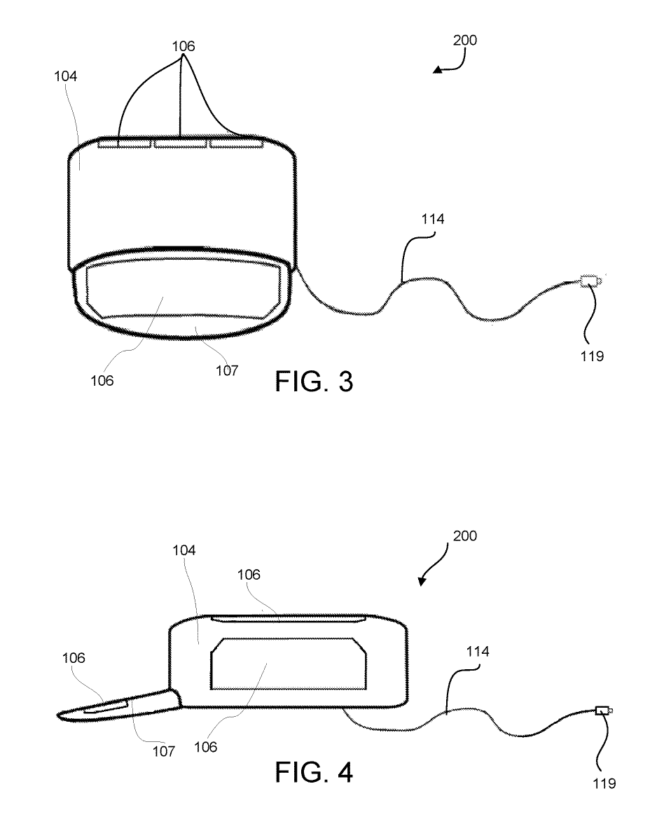

FIG. 3 is a front view of the embodiment of FIG. 2. In some embodiments, only a portion of the article of apparel 104 conforms to a body part such as ahead. For example, in FIGS. 3, a top portion of the article of apparel 104 may be generally planar, such as for example would be found in a military style hat.

FIG. 4 is a side view of the embodiment of FIG. 2. It may be noted by one of ordinary skill in the art, that although the drawing of the sides of article of apparel 104 in FIG. 3 are depicted as being somewhat linear, when an article of apparel 104 such as military hat is worn, it sides will tend to curve to conform to the shape of a wearer's head. If a plurality of crystalline solar cells 106, were attached to sides of a military hat without having first been prepared to accommodate curvature, the curvature of the sides of the military hat may cause the plurality of crystalline solar cells 106, if not adapted to be curvable, to break, which may cause them to become inoperable.

In the embodiments of system 200, the plurality of crystalline solar cells 106 may be pre-stressed at predetermined positions, along predetermined lines, which may have a first predetermined angle and a second predetermined angle as described above with respect to FIG. 1. Thus, the plurality of crystalline solar cells 106 may curve to conform to the article of head apparel 104. Likewise, as described above with respect to FIG. 1 the plurality of crystalline solar cells 106 may be arranged to articulate along the article of head apparel 104. As noted above with respect to FIG. 1 the dimension of the curvature and the dimension of the articulation may be predetermined by a manufacturer of the system.

In other respects, the embodiments of system 200 as depicted in FIGS. 3-5 are substantially similar to the embodiments described above with perspective FIG. 1. In some embodiments, the apparatus 100 and/or the system 200 may be applied to articles of head apparel when a four such as hats including the types of hats described above with respect to FIG. 1. In other embodiments, the article of apparel 104 may include shoulder pads, harnesses, or any other article of apparel 104 suitable to receive at least some sunlight when worn outdoors.

Referring now to FIGS. 5A-5E, 6, 7. FIG. 5A is a top view of an uncut crystalline solar cell 130 suitable for use in the solar charging article of apparel of FIG. 1 and FIG. 2. The uncut crystalline solar cell 130 is depicted with cut lines 103. A method 300 of manufacturing a solar charging apparatus, such as apparatus 100 or system for charging a portable electronic device such as system 200, is depicted. The method begins and includes covering 302 a crystalline solar cell with a flexible top layer 105 which is shown in FIG. 5B.

FIG. 5B is a cross-sectional view of the uncut crystalline solar cell of FIG. 5A with a antireflective layer applied on a top surface of the crystalline solar cell. In some embodiments, the flexible top layer 105 may include an anti-reflective layer such as an anti-reflective adhesive film or coating. An anti-reflective adhesive film or coating may be a micro structured layer that is applied over an uncoated crystalline solar cell to recapture a significant portion of the light that would otherwise be reflected out of the module. A flexible top layer 105 that is an antireflective film that may protect the plurality of crystalline solar cells 106 from coming apart or otherwise being damaged upon being curved. Moreover, an antireflective film or other antireflective top layer community provide a matte finish which may be desirable to avoid reflecting glaring sunlight into eyes or cameras which may be directed toward the article of apparel 104.

With the flexible top layer 105 applied to the crystalline solar cell 106, the method 300 continues and includes cutting 304 the crystalline solar cell 106 into a plurality of crystalline solar cells 106 (e.g., strips). In some embodiments, each of the plurality of crystalline solar cells 106 (e.g., each strip) may be curved at angled pre-stress lines as described above with respect to FIG. 1. The method 300 continues and includes attaching 306 curvable strips to an article of apparel (e.g., 104) so as to conform to the article of apparel (e.g., 104). In some embodiments, the attaching 306 of the method 300 further includes electrically connecting the strips together. Such connecting may be done in series and/or parallel as described above with respect to FIG. 1.

FIG. 5C illustrates a top view of strips cut from the crystalline solar cell of FIG. 5B with polarity markings and further showing electrical connections between the strips, a regulator, and a rechargeable power source. As may be seen in FIG. 5A, the uncut crystalline solar cell 130 has a positive end denoted with a plus sign ‘+’ and a negative and denoted with a minus sign ‘−’. As can be seen in FIG. 5C, one or more of the plurality of crystalline solar cells 106 may be rotated 180° to facilitate connecting the plurality of crystalline solar cells together in series using for example electrical connections 121 so as to configure them to provide a predetermined voltage.

FIG. 5D illustrates a top view of strips cut from the crystalline solar cell and pre-stressed to enable the crystalline solar cell to curve while continuing to function. As described above, the flexible top layer 105 allows the plurality of crystalline solar cells 106 to be pre-stressed along a line, such as pre-stress line 112, which is angled at a second predetermined angle α with respect to a long edge of the strip as pre-stress line 110, which is angled at a second predetermined angle β with respect to the long edge of the strip. As explained above, some angles may be preferable depending on the particular crystalline solar cell. However other angles may also be suitable.

FIG. 5E illustrates a top view of a plurality of crystalline solar cells (e.g., strips) attached to a flexible substrate 108 for attaching so that the curvature of the substrate conforms to the article apparel. The flexible substrate 108 may be formed of a any flexible polymer or other flexible material. A flexible substrate 108 that is durable may assist to protect the plurality of crystalline solar cells 106 from breakage and/or malfunction. Moreover, attaching a plurality of crystalline solar cells 106 that are curvable to a flexible substrate 108 prior to attaching the flexible substrate 108 to the article of apparel 104 may facilitate ease of manufacturing. In some embodiments of the method 300, the plurality of crystalline solar cells 106 may be electrically connected together, and the method 300 ends.

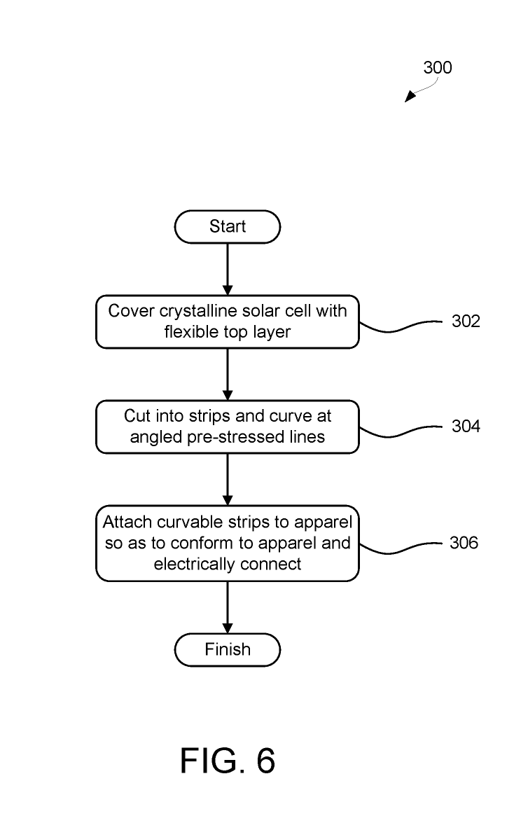

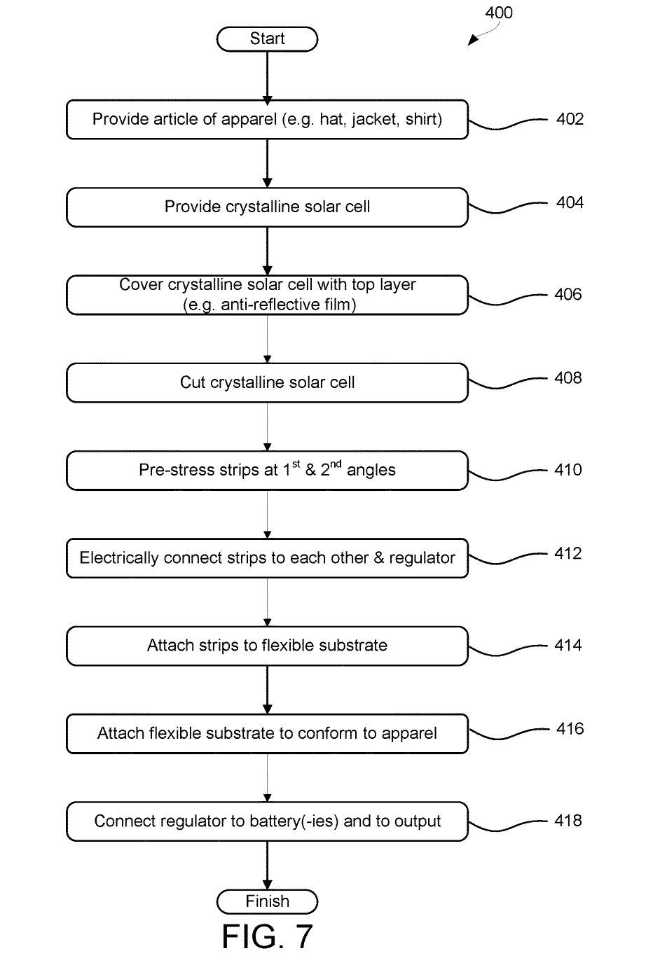

FIG. 7 is a schematic flow diagram illustrating another embodiment of a method 400 of manufacturing a solar charging apparatus and/or system in accordance with some embodiments. The method 400 begins includes providing 402 an article of apparel (e.g., 104). The article of apparel may be any flexible article of apparel such as described above with respect to FIGS. 1 through 6. The method 400 continues and includes providing 404 and uncut crystalline solar cell, such as for example any of the solar cells described above. The method 400 continues and includes covering 406 the uncut crystalline solar cell with a flexible top layer such as flexible top layer 105, as described above with respect to FIGS. 5B, 6.

In some embodiments, the method 400 further includes cutting 408 the uncut crystalline solar cell to which the flexible top layer has been applied, as described above with respect to FIGS. 5B,6. In some environments, the method 400 continues and includes 410 pre-stressing the strips at a first predetermined angle and at a second predetermined angle. The pre-stressing may be done manually, such as by pressing the top layer covered crystalline solar cell against a linear structure such as the edge of the table or counter. Alternatively, the pre-stressing 410 may be done automatically using any automated equipment that would be apparent to one of ordinary skill in manufacturing.

In some embodiments, the method 400 continues includes electrically connecting 412 the strips to each other and electrically connecting the strips to a regulator such as for example, regulator 118 as described above with respect to FIGS. 1-5C. In some embodiments, the method 400 further includes attaching 414 the strips to a flexible substrate, such as for example, the flexible substrate 108 as described above with respect to FIG. 5E. It may noted that any of the steps of method 400 may be performed in any order unless otherwise made clear from the context.

In some embodiments, the method 400 further includes attaching 416 the flexible substrate, such as for example, flexible substrate 108, to the article of apparel (e.g., a baseball cap). In some embodiments, the flexible substrate may be attached using adhesive. In other embodiments, the flexible substrate may be sewn on. Any suitable means of attaching a flexible material to an article of apparel, such that the flexible substrate would substantially conform to the article apparel as the article apparel conforms to a body part, may be used. In some embodiments, the method 400 further includes connecting 418 the regulator to the at least one battery and to the output connector. This may be done substantially as described above with respect to FIGS. 1 through 5C, and the method 400 ends.

The present invention may be embodied in other specific forms without departing from its spirit or essential characteristics. The described embodiments are to be considered in all respects only as illustrative and not restrictive. The scope of the invention is, therefore, indicated by the appended claims rather than by the foregoing description. All changes which come within the meaning and range of equivalency of the claims are to be embraced within their scope.

What is claimed is:

1. An apparatus comprising:
an article of apparel that is capable of conformably fitting to a body part of a wearer, the article of apparel having a longitudinal dimension and a transversal dimension;
a power source that is coupleable to an interior portion of the article of apparel, the power source connected to an output connector that is configured to charge a portable electronic device that is separate from the article of apparel; and
a plurality of crystalline solar cells for recharging the power source, wherein the plurality of crystalline solar cells curves to conform to the article of apparel.

2. The apparatus of claim 1, wherein the plurality of crystalline solar cells comprises a plurality of strips that curve to conform to the article of apparel along the transversal dimension, wherein at least two of the strips in the plurality of crystalline solar cells are arranged to conform to the article of apparel by articulating along the longitudinal dimension of article of apparel.

3. The apparatus of claim 2, wherein the plurality of crystalline solar cells comprises monocrystalline solar cells.

4. The apparatus of claim 3, wherein the plurality of crystalline solar cells further comprises a flexible top layer that covers the crystalline solar cells.

5. The apparatus of claim 4, wherein the flexible top layer comprises an anti-reflective adhesive film.

6. The apparatus of claim 5, wherein the crystalline solar cells, covered by the anti-reflective adhesive film, curve at a plurality of positions that have been pre-stressed at a first predetermined first angle and a second predetermined angle.

7. The apparatus of claim 2, wherein the power source comprises:
at least one rechargeable battery; and
a power regulator configured to regulate an output of the plurality of crystalline solar cells to provide a predetermined voltage for charging the at least one rechargeable battery.

8. The apparatus of claim 7, wherein the power regulator is further configured to regulate a voltage at the output connector.

9. The apparatus of claim 8, wherein the output connector is a universal serial bus (“USB”) connector.

10. The apparatus of claim 7, further comprising an input connector for providing power to charge the at least one rechargeable battery independently from the plurality of crystalline solar cells.

11. The apparatus of claim 7, wherein the at least one rechargeable battery is configured to detachably couple to the article of apparel.

12. The apparatus of claim 11, further comprising a breathable liner configured to attach to the article of apparel and to separate the at least one rechargeable battery from the body part of the wearer.

13. The apparatus of claim 7, wherein the at least one rechargeable battery comprises a lithium-ion chemistry.

14. The apparatus of claim 13, wherein the lithium-ion chemistry comprises lithium iron phosphate.

15. The apparatus of claim 2, wherein the article of apparel is selected from the group consisting of baseball caps, military caps, driving caps, beanies, stocking caps, sun hats, bucket hats, and ski masks.

16. A method of manufacturing a solar charging article of apparel comprising:
covering an uncut crystalline solar cell with a flexible top layer;
cutting the uncut crystalline solar cell into strips and curving the strips at angled pre-stress lines;
attaching the strips to the article of apparel so as to conform to the article of apparel; and
electrically connecting the strips together.

17. The method of claim 16, wherein the angled pre-stress lines are pre-stressed at a first predetermined angle and a second predetermined angle.

18. The method of claim 16, wherein attaching the strips to the article of apparel further comprises attaching the strips to a flexible substrate and attaching the flexible substrate to the article of apparel.

19. The method of claim 16, further comprising electrically connecting the strips to a regulator that regulates an output of the strips to charge a power source.

20. A system comprising:
an article of head apparel that is capable of conformably fitting to a body part of a wearer;
a power source that is coupleable to an interior portion of the article of head apparel, the power source connected to an output connector that is configured to charge a portable electronic device that is separate from the article of head apparel; and
a plurality of crystalline solar cells for recharging the power source, wherein the plurality of crystalline solar cells curves to conform to the article of head apparel.
